(19) United States
(12) Patent Application Publication
(10) Pub. No.: US 2026/0011351 A1
(43) Pub. Date: Jan. 8, 2026

(54) WEIGHTED SUMMATION COMPUTE-IN-MEMORY CIRCUIT AND MEMORY

(71) Applicant: PEKING UNIVERSITY, Beijing (CN)

(72) Inventors: Zongwei WANG, Beijing (CN); Yimao CAI, Beijing (CN)

(73) Assignee: PEKING UNIVERSITY, Beijing (CN)

(21) Appl. No.: 19/115,094

(22) PCT Filed: Jul. 24, 2023
(86) PCT No.: PCT/CN2023/108866

§ 371 Date: Mar. 25, 2025

(30) Foreign Application Priority Data
Apr. 4, 2023 (CN) 202310350594.8

(51) Int. Cl. G11C 5/10; G06G 7/14; G06G 7/16; G11C 8/08

(52) U.S. Cl. CPC G11C 5/10; G06G 7/14; G06G 7/16; G11C 8/08

(57) ABSTRACT

The present disclosure provides a weighted summation compute-in-memory circuit and a memory, the circuit includes: a first array and a second array symmetrically distributed, and a peripheral circuit; when the first array is use for compute-in-memory, the first array is disconnected from the second array through the peripheral circuit, and the first array performs a bitwise array vector multiplication operation; then the first array is connected to the second array through the peripheral circuit, the first array and the second array form a switched-capacitor circuit, the second array performs an analog summation and an analog weighted summation operation corresponding to the pulse signal, and output an operation result.

### CROSS REFERENCE TO RELATED APPLICATIONS

The present application claims priority to Chinese Patent Application No. 202310350594.8, entitled “Weighted Summation Compute-In-Memory Circuit and Memory”, and filed on Apr. 4, 2023, the content of which is expressly incorporated herein by reference in its entirety.

### TECHNICAL FIELD

The present disclosure relates to the field of non-volatile memory and compute-in-memory technology in the ultra-large-scale integrated circuit (ULSI) of a semiconductor and a complementary metal-oxide semiconductor (CMOS), and particularly to a weighted summation compute-in-memory circuit which uses a non-volatile memory array to perform a vector matrix multiplication computation, and a memory.

### BACKGROUND

With continuous development of artificial intelligence and deep learning technologies, artificial neural networks are widely used in fields such as natural language processing, image recognition, autonomous driving, and graph neural networks, etc. However, an increasing network size causes a large amount of energy consumed by data transfer between a memory and a conventional computing device such as a CPU, which is referred to as a von Norman bottleneck. The computation that occupies the most important part in the artificial neural network algorithm is the vector matrix multiplication computation. Based on the compute-in-memory of the non-volatile memory, weight values are stored in a non-volatile memory cell, and analog vector matrix multiplication computation is performed in an array, which avoids frequent data transfers between the memory and the computing unit, and is considered as a promising way to solve the von Neumann bottleneck.

At present, after the weight values are written, the non-volatile memory devices such as RRAM, PCRAM, MRAM, FeRAM, and FeFET, store the weight values in conductivity values of the devices. The devices are arranged into an array, and an input voltage is input from one end as a vector matrix multiplication input. Based on Ohm's law and Kirchhoff's law computation in the array, a current is obtained at the other end of the array, which is a summation result of the vector matrix multiplication. The summation result is generally read out by an analog-to-digital converter (ADC). Since the area of the analog-to-digital converter does not match the area of the array cell area in terms of length, a multiplexer (MUX) is usually employed that enables a plurality of columns in the array to share one analog-to-digital converter.

FIG. 1 is a schematic diagram of performing a vector matrix multiplication based on a non-volatile device array. FIG. 2a and FIG. 2b respectively show two different forms of conventional vector matrix multiplication circuits. In FIG. 2a, an input voltage is input by a digital-to-analog converter, and an output voltage is an operational amplifier clamp bit line voltage. After a current summation is performed on the bit line according to the Kirchhoff's law, the current is converted into a voltage through a Trans-Impedance Amplifier (TIA) formed by an operational amplifier and a resistor, and is finally read out by the analog-to-digital converter. In FIG. 2b, a bit line (BL) parasitic capacitor is precharged to a fixed voltage, a source line is then grounded, and an input pulse is applied on a word line. The quantity of charge lost on the BL parasitic capacitor is equal to the sum of the quantities of charge flowing through the devices. Therefore, a BL voltage drop is equal to a result of multiplying the input by the vector matrix of the weights, and is finally read out by the analog-to-digital converter.

It can be seen that the conventional compute-in-memory circuit has the following problems: since a direct current (DC) process exists in the solution in FIG. 2a, a larger current exists in both the array and the operational amplifier, which affects the further improvement of the system energy efficiency. The DC process does not exist in the solution in FIG. 2b, but since the BL parasitic capacitor is generally smaller and the number of lines activated simultaneously is smaller, the parallelism of computation is affected, and the number of times the analog-to-digital converter operates is increased. In addition, since the BL parasitic capacitor is small, the voltage on the bit line cannot be kept stable under products of different inputs and weights, accordingly computation results are nonlinear.

### SUMMARY

In view of the above, the present disclosure provides a weighted summation compute-in-memory circuit and a memory, in order to address the problem of non-linear computation result caused by the unstable voltage in the existing compute-in-memory circuit, affecting the improvement of the system performance.

The present disclosure provides a weighted summation compute-in-memory circuit, including: a first array and a second array symmetrically distributed, and a peripheral circuit; when the first array is disconnected from the second array through the peripheral circuit, a precharge voltage and a pulse signal are inputted to the first array, and the first array is configured to perform a bitwise array vector multiplication operation; when the first array is connected to the second array through the peripheral circuit, the first array and the second array form a switched-capacitor circuit, the second array is configured to perform an analog summation and an analog weightied summation operation corresponding to the pulse signal, and output an operation result. When the second array is used for the compute-in-memory, the process is similar, and only the first array and the second array perform functional intermodulation.

Optionally, the peripheral circuit comprises a first peripheral circuit corresponding to the first array, a second peripheral circuit corresponding to the second array, and a multiplexer circuit, the multiplexer circuit comprises an operational amplifier, an analog-to-digital converter, a shift register, and an output register; the first peripheral circuit comprises a first input register, a first pulse generator, a first word line driver, a first read and write circuit, a first switch and precharge circuit, and a first switch circuit that are corresponding to the first array; the second peripheral circuit comprises a second input register, a second pulse generator, a second word line driver, a second read and write circuit, a second switch and precharge circuit, and a second switch circuit that are corresponding to the second array.

Optionally, in the first array and the second array, every eight columns of memory cells are divided into one column segment, one 8-bit weight value is represented by one row of 8 memory cells in the column segment; each column segment corresponds to one switch and precharge circuit, one operational amplifier, one analog-to-digital converter, and one shift register.

Optionally, when the first array is disconnected from the second array through the peripheral circuit, a source line of a target column in the first array for a current computation is grounded, all source lines of remaining columns in the same column segment are short-circuited to a bit line, and are precharged to a read voltage through the first switch and precharge circuit; an equivalent capacitance between a bit line of the target column and the ground is equal to: 8*C_{BL}+7*C_{SL}+C_{BS}, where C_{BL} represents a parasitic capacitance between the bit line and the ground, C_{SL} represents a parasitic capacitance between the source line and the ground, and C_{BS} represents a parasitic capacitance between the bit line and the source line.

Optionally, when a precharge circuit between the first array and the read voltage is switched off, a corresponding pulse signal is sent by an external pulse generator on a word line according to a weight value in the first input register, wherein the number of pulse signals is directly proportional to a value in the first input register; a charge on a parasitic capacitor C_{BL} on the bit line loses, and the lost charge is equal to a point multiplication of an input pulse signal and the weight value stored in the first register.

Optionally, when the first array is connected to the second array through the peripheral circuit, a negative input end of the operational amplifier in the multiplexer circuit is configured to be simultaneously connected to the bit line of the target column in the first array and a source line of a corresponding column in the second array, an output end of the operational amplifier is configured to be connected to the bit line of the second array, and a positive input end of the operational amplifier is configured to be connected to the read voltage; the first array, the second array, and the operational amplifier form a switched-capacitor circuit; a voltage of the bit line in the second array is:

V_{BLB}=Q*(C_{BL}+C_{BS})/(8*C_{BL}+7*C_{SL}+C_{BS})/C_{BS},

where C_{BL} represents a parasitic capacitance between the bit line and ground, C_{SL} represents a parasitic capacitance between the source line and ground, and C_{BS} represents a parasitic capacitance between the bit line and the source line.

Optionally, the voltage of the bit line in the second array is proportional to the amount of charge lost.

Optionally, the first array is configured to input a multi-value voltage through an external digital-to-analog converter, or input a binary voltage through a buffer; an output of the second array is converted through the analog-to-digital converter, and a converted digital quantity is stored into the shift register to complete outputting.

Optionally, both the first array and the second array comprise N columns and M rows of memory cells, and a memory cell is a 1T1R device.

In another aspect of the present disclosure, a memory is provided, including the above-mentioned weighted summation compute-in-memory circuit.

With the above-mentioned weighted summation compute-in-memory circuit and memory, a first array and a second array symmetrically distributed, and a peripheral circuit are provided. At first, the first array may be disconnected from the second array, a precharge voltage and a pulse signal may be inputted into the first array, and the first array performs a bitwise array vector multiplication operation. Then, the first array is connected to the second array through the peripheral circuit, to form a switched-capacitor circuit, and then the second array performs an analog summation and an analog weighted summation operation, and outputs an operation result corresponding to the pulse signal, so that a requirement for an area by additionally adding a capacitor to complete the process is eliminated, the number of startup times of the ADC is reduced, and the energy efficiency and area efficiency of the system are improved.

In order to implement the foregoing and related purpose, one or more aspects of the present disclosure include limitations described in detail later. Some exemplary aspects of the present disclosure are elaborated in the following description and accompanying drawings. However, these aspects indicate merely some of the various manners in which the principle of the present disclosure may be used. In addition, the present disclosure is intended to include all these aspects and equivalents thereof.

### BRIEF DESCRIPTION OF THE DRAWINGS

By referring to the following description with reference to the accompanying drawings, and as the present disclosure becomes more fully understood, other purposes and effects of the present disclosure will become clearer and easier to understand. In the accompanying drawings:

FIG. 1 is a schematic diagram of a matrix multiplication performed based on a non-volatile device array.

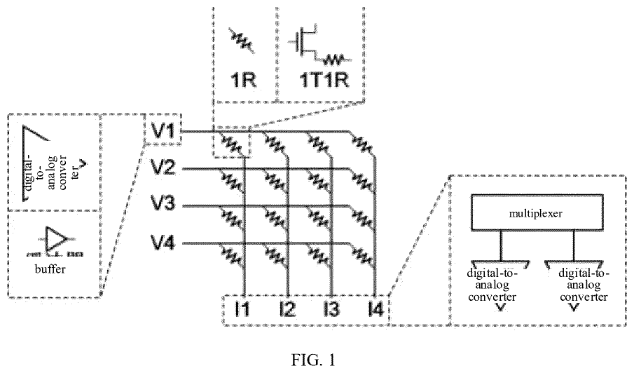

FIG. 2a is a circuit diagram I of a vector matrix multiplication performed in a conventional array.

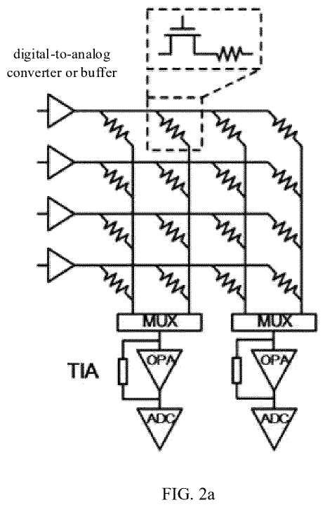

FIG. 2b is a circuit diagram II of a vector matrix multiplication performed in a conventional array.

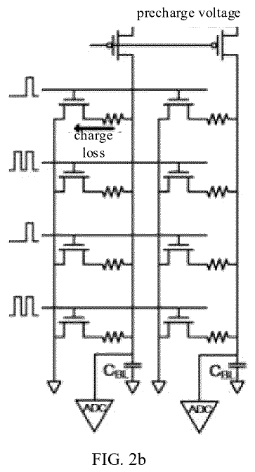

FIG. 3 is a schematic structure diagram of a weighted summation compute-in-memory circuit according to an embodiment of the present disclosure.

FIG. 4 is a schematic structure diagram of a switch and precharge circuit of a symmetric array according to an embodiment of the present disclosure.

FIG. 5 is a schematic diagram of a weighted summation compute-in-memory circuit in an operation process step I according to an embodiment of the present disclosure.

FIG. 6 is a schematic diagram of a weighted summation compute-in-memory circuit in an operation process step II according to an embodiment of the present disclosure.

FIG. 7 is a schematic diagram of a weighted summation compute-in-memory circuit in an operation process step III according to an embodiment of the present disclosure.

FIG. 8 is a schematic diagram of implementing a weighted summation computation by using a symmetric array parasitic capacitor.

### DETAILED DESCRIPTION

In the following description, for the purpose of illustration, many specific details are described below in order to provide a comprehensive understanding of one or more embodiments. However, it is obvious that these embodiments may also be implemented without these specific details. In other examples, for ease of describing one or more embodiments, well-known structures and devices are shown in a block diagram form.

In the current compute-in-memory solution, due to a DC process, there exista a larger current in both the array and the operational amplifier, which affects the further improvement of the system energy efficiency. In addition, although the DC process may be omitted, since a bit line (BL) parasitic capacitor is generally smaller and the number of open lines is smaller, the parallelism of the computation is affected, and the number of operation cycles of an analog-to-digital converter is increased. In addition, since the BL parasitic capacitor is smaller, a voltage on the bit line cannot be kept stable under products of different inputs and weights, accordingly the computation results are nonlinear. In order to address the above-mentioned problem, the present disclosure provides a compute-in-memory circuit in which a bit line capacitor is added by using an adjacent cell and a weighted summation is performed by using a symmetric array parasitic capacitor. The compute-in-memory circuit mainly includes two symmetric arrays, i.e., a first array and a second array, and corresponding peripheral circuits that are independent or multiplexed. When the first array is configured to perform a bitwise matrix vector multiplication computation in a neural network, the second array is configured to provide a parasitic capacitor to implement the weighted summation computation, so that a computation capacitor for computing a column bit line can be added through a parasitic capacitor of an adjacent column, the voltage is kept stable, the accuracy of the computation is improved, and the analog summation and the analog weighted summation are completed by using the symmetric array. Accordingly, a requirement for the area by additionally adding a capacitor to complete the process is eliminated, the number of startup times of the ADC is reduced, and the energy efficiency and area efficiency of the system are improved.

In an implementation mode of the present disclosure, the first array inputs a multi-value voltage through an external digital-to-analog converter, or inputs a binary voltage through a buffer, and an output of the second array is converted through an analog-to-digital converter, and the converted digital quantity is stored into a shift register to complete the outputting. In addition, both the first array and the second array include N columns and M rows of memory cells. Specifically, N and M may be positive integers, and the memory cell may be a 1T1R device or the like.

Since the 1T1R device can avoid a problem of writing crosstalk, the 1T1R device is generally used in a large array. In the description of the present disclosure, it should be appreciated that the 1T1R device is taken as an example for description. Accordingly, in an agreed naming manner, a line connected to a gate of a transistor is referred to as a Word Line (WL), a line connected to a source of a transistor is referred to as a Source Line (SL), and a line connected to one end of the device is referred to as a Bit Line (BL).

In order to detail the weighted summation compute-in-memory circuit and the mamory of the present disclosure, the specific embodiments of the present disclosure will be elaborated with reference to the accompanying drawings.

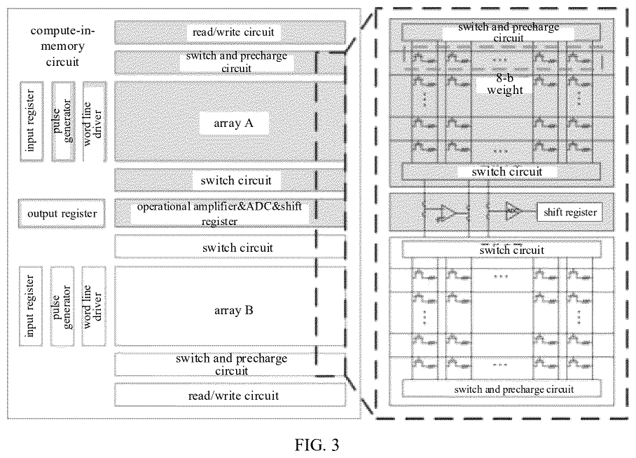

FIG. 3 is a schematic structure diagram of a weighted summation compute-in-memory circuit according to an embodiment of the present disclosure.

As shown in FIG. 3, the weighted summation compute-in-memory circuit implemented in the present disclosure includes a first array (array A) and a second array (array B) symmetrically distributed, and a multiplexed or exclusive peripheral circuit. The first array is connected to or disconnected from the second array through the peripheral circuit. When the first array is disconnected from the second array through the peripheral circuit, a precharge voltage and a pulse signal may be inputted to the first array, and a bitwise array vector multiplication operation is performed by the first array. When the first array is connected to the second array through the peripheral circuit, the first array and the second array form a switched-capacitor circuit, so that the second array can perform the analog summation and the analog weightied summation, and output an operation result corresponding to the pulse signal, thereby implementing the compute-in-memory of the weighted summation.

Specifically, the peripheral circuit may further include a first peripheral circuit corresponding to the first array, a second peripheral circuit corresponding to the second array, and a multiplexer circuit. The multiplexer circuit is located between the first array and the second array, and can be used by both the first array and the second array. The multiplexer circuit may include an operational amplifier, an analog-to-digital converter, a shift register, and an output register. The first peripheral circuit may include a first input register, a first pulse generator, a first word line driver, a first read and write circuit, a first switch and precharge circuit, and a first switch circuit that are corresponding to the first array. The second peripheral circuit may include a second input register, a second pulse generator, a second word line driver, a second read and write circuit, a second switch and precharge circuit, and a second switch circuit that are corresponding to the second array. The connection state and disconnection state between the first array and the second array can be switched through cooperation of the first switch circuit and the second switch circuit.

Further, in the first array and the second array, every eight columns of memory cells are divided into one column segment. One 8-bit weight value is represented by one row of 8 memory cells in the column segment. In addition, each column segment corresponds to one switch and precharge circuit, one operational amplifier, one analog-to-digital converter, and one shift register. The operational amplifier and the analog-to-digital converter may be connected to the first array or the second array by the switching of the switch circuit (including a first switch circuit and a second switch circuit), and the digital quantity outputted by the analog-to-digital converter is stored in the shift register and is finally transmitted to the output register.

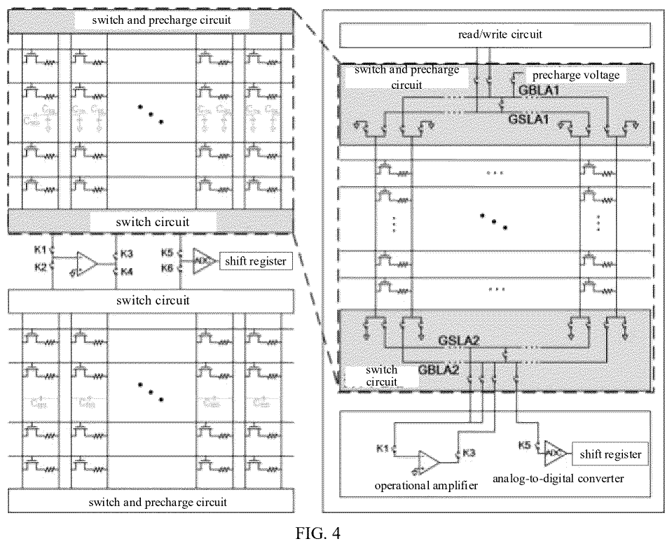

As a specific example, FIG. 4 shows a schematic structure diagram of a switch and precharge circuit of a symmetric array according to an embodiment of the present disclosure.

As shown in FIG. 4, the first array is taken as an example for description. A dotted line portion with a gray scale on the right side in the figure is a partial amplification structure of a dotted line portion with a gray scale on the left side. In each column segment, all bit lines are connected to each other or grounded through a switch and a common bit line (GBLA1, GBLA2), and all source lines are connected to each other or grounded through a switch and a common source line (GSLA1, GSLA2). Common bit lines in different column segments are unconnected to the common source line. In the switch and precharge circuit on a lateral side of the array (the first switch and are charge circuit on an upper side of the first array), the common bit line GBLA1 is connected to a precharge voltage through a switch on a corresponding side. The common bit line GBLA1 and the common source line GSLA1 are connected to a read and write circuit through a switch. The common bit line GBLA1 may be short-circuited to the common word line GSLA1 through a switch. In a switch circuit on the inner side of the array (a first switch circuit on a lower side of the first array), the common bit line GBLA2 is connected to a negative input end or an output end of the operation amplifier, or an input end of the analog-to-digital converter through a switch, the common source line GSLA2 is connected to the negative input end of the operation amplifier through a switch, and the common bit line may be short-circuited to the common word line through a switch.

It should be noted that the second array and the first array are symmetrically distributed. For an internal structure of the second array, reference can be made to description of the first array, and the details are not described herein again.

As a specific example, a specific operation principle (an operation process) of the weighted summation compute-in-memory circuit is described in detail below.

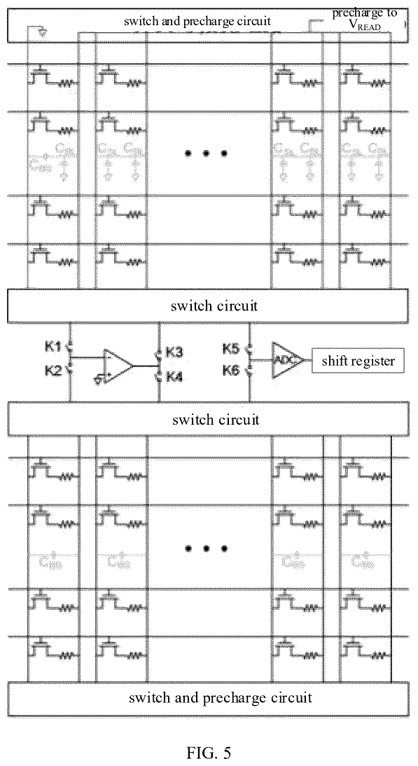

Specifically, FIG. 5 shows a schematic structure diagram of a weighted summation compute-in-memory circuit in an operation process step I according to an embodiment of the present disclosure.

As shown in FIG. 5, in the operation process step I, when the first array is configured to perform the bitwise matrix vector multiplication computation in a neural network, a source line of a column for the computation (that is, a target column) in a column segment of the first array is grounded, all source lines of remaining columns in the same column segment are short-circuited to a bit line, and are precharged to a read voltage V_{READ} through the first switch and precharge circuit. At this time, an equivalent capacitance between the bit line of the target column and the ground is equal to: 8*C_{BL}+7*C_{SL}+C_{BS}, where C_{BL} represents a parasitic capacitance between the bit line and the ground, C_{SL} represents a parasitic capacitance between the source line and the ground, and C_{BS} represents a parasitic capacitance between the bit line and the source line. This equivalent capacitance is far larger than the only parasitic capacitance between the bit line and the ground used in the conventional method. Therefore, a bit line precharge capacitance is increased, and the problem of small number of activated lines and non-linearity caused by the small bit line parasitic capacitance in the conventional method is solved.

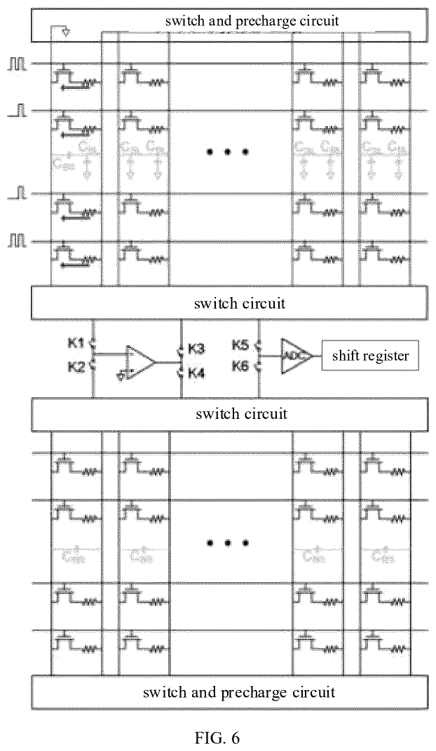

In addition, FIG. 6 shows a schematic structure diagram of a weighted summation compute-in-memory circuit in an operation process step II according to an embodiment of the present disclosure.

As shown in FIG. 6, in the operation process step II, the precharge switch in the first switch and precharge circuit is off, and a specific quantity of pulse signals are sent by an external pulse generator through a word line according to a weight value in the input register, that is, when the precharge circuit between the first array and the read voltage is disconnected, a corresponding pulse signal is sent by the external pulse generator on the word line according to a weight value in the first input register. The number of the pulse signals is directly proportional to a value in the first input register. The charge on the parasitic capacitor C_{BL} located on the bit line loses, and the lost charge Q is equal to a point multiplication of an input pulse signal and a weight value stored in the first register.

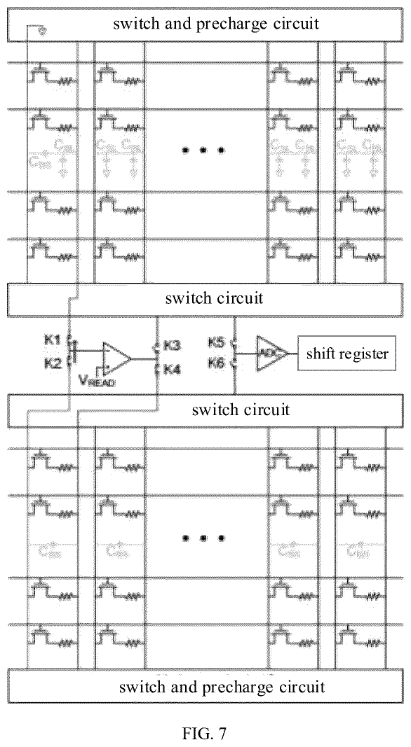

In addition, FIG. 7 shows a schematic structure diagram of a weighted summation compute-in-memory circuit in an operation process step III according to an embodiment of the present disclosure.

As shown in FIG. 7, in the operation process step III, a bit line of a column in the first array currently used for calculation is disconnected from other source lines and bit lines, and switches K1, K2, and K4 are turned on, that is, the switches K1, K2, and K4 are switched on, while switches K3, K5, and K6 are turned off. The negative input end of the operational amplifier is simultaneously connected to the bit line of the column in the first array currently used for calculation and a source line of a corresponding column in the second array. The output end of the operational amplifier is connected to the bit line in the second array, a positive input end of the operational amplifier is connected to the read voltage V_{READ}, and the operational amplifier and the two arrays form a switched-capacitor circuit.

In other words, when the first array is connected to the second array through a peripheral circuit, the negative input end of the operational amplifier in the multiplexer circuit is simultaneously connected to a bit line of a target column in the first array and a source line of a corresponding column in the second array, the output end of the operational amplifier is connected to the bit line of the second array, and a positive input end of the operational amplifier is connected to the read voltage. The first array, the second array, and the operational amplifier form a switched-capacitor circuit.

The charge lost by the bit line in the first array in the step II is compensated by a parasitic capacitor in the second array. Since the charge of the second array flows out of the source line, the bit line voltage rises. At this time, assuming that the charge lost by the bit line equivalent capacitor of the first array in the step II is Q, after the step III ends, the raised voltage of the bit line in the second array is:

$${V}_{BLB} = Q * ( {C}_{BL} + {C}_{BS} ) / ( 8 * {C}_{BL} + 7 * {C}_{SL} + {C}_{BS} ) / {C}_{BS}$$

where C_{BL} represents a parasitic capacitance between the bit line and ground, C_{SL} represents a parasitic capacitance between the source line and ground, and C_{BS} represents a parasitic capacitance between the bit line and the source line. This voltage is proportional to the charge Q, that is, proportional to a point multiplication of an input pulse and a weight value.

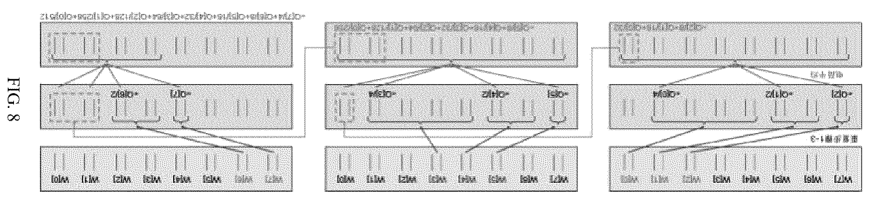

FIG. 8 shows a principle of implementing a weighted summation computation using a symmetric array parasitic capacitor.

As shown in FIG. 8, one column segment includes eight columns of memory cells or devices, and one row of eight devices represents an 8-bit weight value, which is represented as W[7:0]. In order to implement the weighted summation computation by using the parasitic capacitor of the array B, the aforementioned steps I to III are first repeated three times, the first repeat is for computing a column representing W[2], and one column bit line is connected to in the array B during the charge distribution process of the step III. The second repeat is for computing a column representing W[1], and two column bit lines are connected to in the array B during the charge distribution process of the step III. The third repeat is for computing a column representing W[0], and four column bit lines are connected to in the array B during the charge distribution process of the step III.

After each of the above-mentioned there repeat processes, one column bit line is selected from the bit lines in the array B to hold the charge, and charges corresponding to the remaining five columns are cleared. Finally, charge averaging is performed on the eight columns in the array B. Assuming that Q[2] denotes a charge lost by an equivalent capacitor on the bit line when W[2] is computed for the array A, Q[1] denotes a charge lost by an equivalent capacitor on the bit line when W[1] is computed for the array A, and Q[0] denotes a charge lost by an equivalent capacitor on the bit line when W[0] is computed for the array A, then the voltage VI obtained in the array B after the computation ends is expressed as: V1∝Q[2]/8+Q[1]/16+Q[0]/32, and then the voltage remains unchanged in the last column of the array B, and W[5:3] is computed by using the first 7 columns.

Specifically, the aforementioned steps I to III are repeated again for three times, the first repeat computes a column representing W[5], and one column bit line is connected to in the array B during the charge distribution process of the step III. The second repeat computes a column representing W[4], and two column bit lines are connected to in the array B during the charge distribution process of the step III. The third repeat computes a column representing W[3], and four column bit lines are connected to in the array B during the charge distribution process of the step III, and then one column bit line is selected from the bit lines in the array B for each of the three repeat processes to hold the charge respectively after the each of the three repeat processes ends, plus the column holding the voltage V1 after the previous computation, and charges corresponding to the remaining four columns are cleared. Finally, charge averaging is performed on the eight columns in the array B. Assuming that Q[5] denotes a charge lost by an equivalent capacitor on the bit line when W[5] is computed for the array A, Q[4] denotes a charge lost by an equivalent capacitor on the bit line when W[4] is computed for the array A, and Q[3] denotes a charge lost by an equivalent capacitor on the bit line when W[3] is computed for the array A, then the voltage V2 obtained in the array B after the computation ends is expressed as:

$$V 2 ∝ Q [ 5 ] / 8 + Q [ 4 ] / 16 + Q [ 3 ] / 32 + Q [ 2 ] / 64 + Q [ 1 ] / 128 + Q [ 0 ] / 256 ,$$

so that the voltage V2 remains unchanged in the last two columns of the array B, and W[7:6] is computed by using 3 of the first 6 columns. The aforementioned steps I to III are repeated two more times, the first repeat computes a column representing W[7], and one column bit line is connected to in the array B during the charge distribution process of the step III. The second repeat computes a column representing W[6], and two column bit lines are connected to in the array B during the charge distribution process of the step III. Then one column bit line is selected from the bit lines in the array B for each of the two repeat processes to hold the charge respectively after the each of the two repeat processes ends, and the two columns with the voltage V2 held after the previous computation, and than the charge averaging is performed on these four columns. It is assumed that Q[7] denotes a charge lost by an equivalent capacitor on the bit line when W[7] is computed for the array A, Q[6] denotes a charge lost by an equivalent capacitor on the bit line when W[6] is computed for the array A, then the voltage V3 obtained in the array B after the computation ends is expressed as:

$$V 3 ∝ Q [ 7 ] / 4 + Q [ 6 ] / 8 + Q [ 5 ] / 16 + Q [ 4 ] / 32 + Q [ 3 ] / 64 + Q [ 2 ] / 128 + Q [ 1 ] / 256 + Q [ 0 ] / 512.$$

Accordingly, the shift summation (that is, binary weighted summation) computation of different columns is implemented. The finally obtained voltage V3 is connected to an analog-to-digital converter through a switch K6, a digital quantity read out is stored in the shift register, and is finally stored in the output register to complete the output.

It should be noted that, since the first array and the second array are symmetrically distributed, the second array may be further configured to perform a bitwise matrix vector multiplication computation in the neural network, and the first array is configured to provide a parasitic capacitor for implementing weighted summation computation. The computation process is the same as that in the foregoing process, that is, the first array and the second array may be functionally interchangeable. The specific circuit operation principles thererof are the same, and details are not described herein again.

Corresponding to the above-mentioned weighted summation compute-in-memory circuit, the present disclosure further provides a memory including the above-mentioned weighted summation compute-in-memory circuit. A type of the memory may include SRAM, DRAM, RRAM, PCRAM, MRAM, FeRAM, FeFET, and the like.

It should be noted that for a specific embodiment of the above-mentioned memory, reference may be made to description in the embodiments of the weighted summation compute-in-memory circuit, and details are not described herein again.

According to the weighted summation compute-in-memory circuit and the memory in the present disclosure, an area occupied by additionally adding a capacitor to complete the process can be eliminated, the number of startup times of ADC is reduced, the parallelism of computation is not affected, and the computational performance and area efficiency of the system are improved.

It should be further noted that in the specification, relationship terms such as the first and the second are only used for distinguishing one entity or operation from another, and do not necessarily require or imply that there exists any such actual relationship or sequence between these entities or operations. In addition, terms “include”, “comprise” or any other variant thereof is intended to cover non-exclusive inclusion such that a process, method, article or device includes a series of elements includes not only those elements but also other elements not explicitly listed, or includes elements inherent in such a process, method, article or device. In the absence of more restrictions, an element defined by the statement “including a . . . ” does not exclude other same elements in the process, method, article, or device that includes the element.

The above-mentioned description of the disclosed embodiments enables a person skilled in the art to implement or use the present disclosure. Various modifications to these embodiments can be obvious to those skilled in the art, and the general principle defined herein may be implemented in other embodiments without departing from the spirit or scope of the present disclosure. Therefore, the present disclosure is not limited to these embodiments shown herein, but should meet the widest range consistent with the principle and novel features disclosed herein.

1. A weighted summation compute-in-memory circuit, comprising: a first array and a second array symmetrically distributed, and a peripheral circuit, wherein
when the first array is disconnected from the second array through the peripheral circuit, a precharge voltage and a pulse signal are inputted to the first array, and the first array is configured to perform a bitwise array vector multiplication operation;
when the first array is connected to the second array through the peripheral circuit, the first array and the second array form a switched-capacitor circuit, and the second array is configured to perform an analog summation and an analog weightied summation operation corresponding to the pulse signal, and output an operation result.

2. The weighted summation compute-in-memory circuit according to claim 1, wherein the peripheral circuit comprises a first peripheral circuit corresponding to the first array, a second peripheral circuit corresponding to the second array, and a multiplexer circuit, wherein
the multiplexer circuit comprises an operational amplifier, an analog-to-digital converter, a shift register, and an output register;
the first peripheral circuit comprises a first input register, a first pulse generator, a first word line driver, a first read and write circuit, a first switch and precharge circuit, and a first switch circuit that are corresponding to the first array;
the second peripheral circuit comprises a second input register, a second pulse generator, a second word line driver, a second read and write circuit, a second switch and precharge circuit, and a second switch circuit that are corresponding to the second array.

3. The weighted summation compute-in-memory circuit according to claim 2, wherein in the first array and the second array, every eight columns of memory cells are divided into one column segment, one 8-bit weight value is represented by one row of 8 memory cells in the column segment; and
each column segment corresponds to one switch and precharge circuit, one operational amplifier, one analog-to-digital converter, and one shift register.

4. The weighted summation compute-in-memory circuit according to claim 3, wherein when the first array is disconnected from the second array through the peripheral circuit, a source line of a target column in the first array for a current computation is grounded, all source lines of remaining columns in the same column segment are short-circuited to a bit line, and are precharged to a read voltage through the first switch and precharge circuit; and
an equivalent capacitance between a bit line of the target column and the ground is equal to: 8*C_{BL}+7*C_{SL}+C_{BS}, where C_{BL} represents a parasitic capacitance between the bit line and the ground, C_{SL} represents a parasitic capacitance between the source line and the ground, and C_{BS} represents a parasitic capacitance between the bit line and the source line.

5. The weighted summation compute-in-memory circuit according to claim 4, wherein when a precharge circuit between the first array and the read voltage is disconnected, a corresponding pulse signal is sent by an external pulse generator on a word line according to a weight value in the first input register, wherein the number of pulse signals is directly proportional to a value in the first input register; and
a charge on a parasitic capacitor C_{BL} on the bit line loses, and the lost charge is equal to a point multiplication of an input pulse signal and the weight value stored in the first register.

6. The weighted summation compute-in-memory circuit according to claim 5, wherein when the first array is connected to the second array through the peripheral circuit, a negative input end of the operational amplifier in the multiplexer circuit is configured to be simultaneously connected to the bit line of the target column in the first array and a source line of a corresponding column in the second array, an output end of the operational amplifier is configured to be connected to the bit line of the second array, and a positive input end of the operational amplifier is configured to be connected to the read voltage;
the first array, the second array, and the operational amplifier form a switched-capacitor circuit;
a voltage of the bit line in the second array is:
$${V}_{BLB} = Q * ( {C}_{BL} + {C}_{BS} ) / ( 8 * {C}_{BL} + 7 * {C}_{SL} + {C}_{BS} ) / {C}_{BS} ,$$
where C_{BL} represents a parasitic capacitance between the bit line and ground, C_{SL} represents a parasitic capacitance between the source line and ground, and C_{BS} represents a parasitic capacitance between the bit line and the source line.

7. The weighted summation compute-in-memory circuit according to claim 6, wherein the voltage of the bit line in the second array is proportional to the amount of charge lost.

8. The weighted summation compute-in-memory circuit according to claim 2, wherein the first array is configured to input a multi-value voltage through an external digital-to-analog converter, or input a binary voltage through a buffer; and
an output of the second array is converted through the analog-to-digital converter, and a converted digital quantity is stored into the shift register to complete outputting.

9. The weighted summation compute-in-memory circuit according to claim 1, wherein both the first array and the second array comprise N columns and M rows of memory cells, and the memory cell is a 1T1R device.

10. A memory, comprising a weighted summation compute-in-memory circuit, wherein the weighted summation compute-in-memory circuit comprises: a first array and a second array symmetrically distributed, and a peripheral circuit, wherein
when the first array is disconnected from the second array through the peripheral circuit, a precharge voltage and a pulse signal are inputted to the first array, and the first array is configured to perform a bitwise array vector multiplication operation;
when the first array is connected to the second array through the peripheral circuit, the first array and the second array form a switched-capacitor circuit, and the second array is configured to perform an analog summation and an analog weighted summation operation corresponding to the pulse signal, and output an operation result.
